(19) United States
(12) Patent Application Publication
(10) Pub. No.: US 2004/0224427 A1
(43) Pub. Date: Nov. 11, 2004

(54) [A DETECTION METHOD FOR METAL CONTAMINATION AND MICRO PARTICLES OF A FABRICATION DEVICE]

(76) Inventors: Wen-Guang Yu, Taichung (TW); Liang-Tien Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,757

(22) Filed: May 6, 2003

(51) Int. Cl. H01L 21/66; G01R 31/26

(52) U.S. Cl. 438/14; 438/16

(57) ABSTRACT

A detection method for metal contamination and micro particles of a fabrication device is disclosed. The method comprises providing a control chip; transferring the control chip to a fabrication device so that the control chip is treated by the fabrication device; removing the control chip from the fabrication device; forming a silicon material layer on the control chip; and measuring the number of particles and defects formed on the silicon material layer of the control chip. Therefore, the extent of metallic contamination and micro particle of the fabrication device can be determined.

### BACKGROUND OF INVENTION

1. Field of the Invention

The present invention relates to a detection method for metal contamination and micro particles, and in particular, a detection method for metal contamination and micro particles of a semiconductor fabrication device.

2. Description of the Related Art

Integrated circuit (IC) is an electronic product with an area of about 2 cm² or smaller area containeing a specific circuit having various elements and wirings. As a result, the IC is a combination of thousands of solid state electronic elements which can only be seen under a microscope. Therefore, it is also known as micro electronic elements.

Currently, the trend of development of semiconductor IC technology is towards the revolution of smaller width wire. As a result, the requirements of cleanliness of the fabrication device are strict. The semiconductor devices, for instance: fabrication devices for film deposition, dry etching, ion implantation and micro imaging, etc., have to be operated under an environment of appropriate cleanliness. In addition, the flow chart for IC fabrication is very complicated which requires tens or hundreds of different steps to accomplish. Thus, it is probable that a wafer may be contaminated by impurities, for instance, metal or micro particles at each of the fabrication steps. Therefore, it is very important to detect the environment in each fabrication device.

The conventional method of detecting metal contamination and micro particles within the fabrication device is by using a vacant chip, non-patterned control chip or product to detect metal and micro particles. When the vacant chip or non-patterned control chip to detect metal and micro particles is used, the control chip is placed into the fabrication device under test and the fabrication device is used to treat the control chip. After treatment of the control chip equipment, for instance, a total reflective x-ray fluorescence (TXRF) or inductive couple plasma mass spectroscopic (ICP-MS), is used to measure the number of particles and defects on the control chip. However, the TXRF can be used in measuring, however, the sensitivity of detection is poor. The equipment cannot fully detect the slightest amount of metal contamination, for instance, elemental state metal or metal ions. Thus, when TXRF is employed, appropriate samplings have to be used. For instance, the ICP-MS has a good sensitivity; however, the ICP-MS cannot directly proceed to measurement and a chemical pre-treatment analysis step is required. Therefore, the step may cause the loss of the sample or the sample may be contaminated, and additionally the pre-treatment steps are complicated and laborious. Therefore, the above equipment cannot rapidly and effectively detect the amount of metal contamination and micro particles within the fabrication device.

If a product is directly tested for metal contamination and micro particles within the fabrication device, when the product is detected to have a problem the production has to be stopped (stop operation of the fabrication device) in order to detect the metal contamination and micro particles, the lag between detecting that the product has problems and the initial product generated within the fabrication device in the course of fabrication is about half a day, and to stop production and to proceed with detection of metal contamination and micro particle needs half a day. Thus, since the conventional method cannot instantaneously reflect the state of fabrication device, the capacity and the yield of product can easily be affected.

### SUMMARY OF INVENTION

Accordingly, it is an object of the present invention to provide a detection method for metal contamination and micro particles of a fabrication device, which can rapidly and effectively detect the amount of metal contamination and micro particles of the fabrication device, so as to mitigate the drawbacks of conventional detection methods.

Yet another object of the present invention is to provide a detection method for metal contamination and micro particles of a fabrication device, which effectively and instantaneously reflects the status of the product, providing immediate cleaning of the device if a defect product is discovered.

A further object of the present invention is to provide a detection method for metal contamination and micro particles of a fabrication device, wherein the control chip is placed in the fabrication device under test. An example of a fabrication devices includes equipment used in semiconductor fabrication process and the control chip which has undergone treatment by the fabrication device. After that, a silicon material layer is formed on the control chip so as to signify the position of the metal contamination and micro particles on the control chip.

In accordance with the present invention, a silicon material layer is formed on the treated control chip, and an existing measuring equipment, for instance, TXRF, is used to measure the number of particles and defects formed on the silicon material layer of the control chip without incurring cost for additional expensive equipment. Therefore, less money and time are required in achieving a better effect than those currently employed by measuring equipment such as TXRF.

Therefore, the present invention relates to the formation of silicon material layer on a treated control chip and the number of particles and defects on the formed silicon material layer is measured using a measuring equipment. Therefore, metal contamination and micro particles can be first detected before a product is produced to effectively avoid the impact on the yield as a result of metal contamination and micro particles. Or in the course of fabricating a product, if a defect product is detected, detection of metal contamination and micro particles is immediate, effectively and instantaneously reflecting the state of the product. If a problem on the fabrication device is discovered, an immediate cleaning of device can be proceeded.

Other than detection of metal contamination and micro particles of a fabrication device, the actual delivery process of a product within the fabrication device can be simulated. The application and above method of measuring metal contamination and micro particles in the fabrication device are different in that the application uses a control chip to simulate a product in the actual delivery process within the fabrication device without proceeding to fabrication treatment. The present invention can also simulate a product, which has undergone metal contamination and micro particles, in the course of in earlier stage treatment, within the fabrication device.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve the principles of the invention.

In the drawings, FIG. 1 is a flowchart showing method of detection of metallic contamination and micro particles of the fabrication device using a control chip in accordance with the present invention.

FIG. 2 is a schematic view showing bumps formed at the metallic impurities position after the silicon material layer is formed in accordance with the present invention.

FIG. 3 is a schematic view showing bumps formed at the micro particles position after the silicon material layer is formed in accordance with the present invention.

FIG. 4 is a flowchart of detection of metallic contamination and micro particles, using a control chip simulating of the product in actual delivery process of the fabrication process in accordance with the present invention.

FIG. 5A is a diagram showing the impurities distribution on the control chip surface of a deposited silicon material layer in accordance with the present invention.

FIG. 5B is a diagram showing the impurities distribution on the control chip surface on a non-deposit silicon material layer in accordance with the present invention.

FIG. 5C is an impurities distribution diagram of a product on the deposited silicon material layer in accordance with the present invention.

### DETAILED DESCRIPTION

Reference will now be made in detail of the present preferred embodiments of the invention, examples of which are illustrated in the accompanying drawings. Wherever possible, the same reference numbers are used in the drawings and the description to refer to the same or like parts.

Referring to FIG. 1, there is shown a flowchart of the present method of detecting metal contamination and micro particles in a fabrication device.

Step 100: providing a control chip, for instance a vacant chip or a non-pattern control chip.

Step 120: placing the control chip in the fabrication device under test. The fabrication devices include devices for film deposition, dry etching, ion implantation and micro imaging. These fabrication devices are used to proceed the control chip to film deposition, dry etching, ion implantation and micro imaging.

Step 140: forming a silicon material layer on the control chip. The silicon material layer includes polycrystalline silicon, amorphous silicon and epitaxial silicon. The method of forming silicon material layer includes, for instance, chemical vapour deposition when the temperature of the silicon material formed on the control chip is about 600 Â° C. to 750 Â° C., the thickness of the silicon material layer is 550 \overline{A}□.

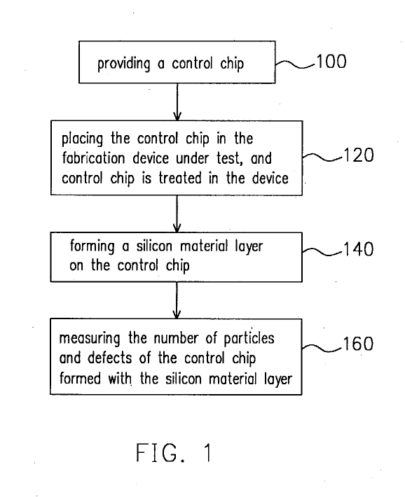

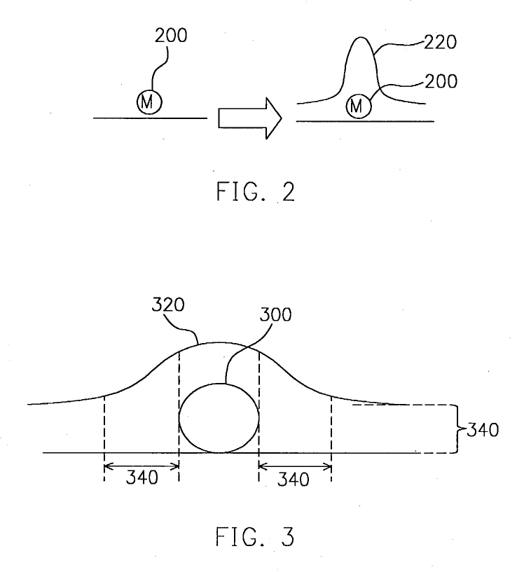

The formation of silicon material layer on the control chip is through the step 140. If there are metal contamination and micro particles on the control chip, these metal contamination and micro particles will form chemical or physical reaction mechanism with the silicon material layer. In accordance with the present invention, the physical and chemical reaction mechanism is used to signify the metal contamination and micro particles position, such that the subsequent measured result is closer to actual contamination of the product within the fabrication device. FIGS. 2 and 3 are referred to for the description as follows.

FIG. 2 is a schematic view showing bumps formed at the metallic impurities position after the silicon material layer is formed. If the control chip contains metal 200 contamination, the silicon atom and metal of the subsequent formed silicon material layer react to form metallic silicon oxide on the control chip surface, forming into horn-like bulge 220. Thus, metal 200 contamination, for instance metal particle, even the slightest elemental metal or metallic ions can be fully detected. Next, referring to FIG. 3, there is shown the lateral view of the bulge on the micro particle position after silicon material layer is formed. With respect to other contamination, for instance, the micro particle 300, due to subsequent step of silicon material layer, on the micro particle 300 position, forms a bump 320 of size of one times the particle diameter plus two times the thickness and height of the particle diameter. Generally, a micro particle 300 will cause a defect of similar width as that of the particle diameter. If the detection limit of a measuring device is, for example 0.145 Î¼m, no silicon material layer being formed on the control chip, if the control chip contains micro particles, the detected minimum size of the defect is 0.145 Î¼m. However, based on the thickness 340 of the silicon material layer of the present invention, for instance, being 550 Ã□, the place where micro particles are present will be formed into bump. The range of the bump is about twice the thickness (1100 Ã□) plus one time the diameter of the particle. By using the similar equipment for measuring (limitation of detection being 0.145 Î¼m) the minimum defect that can be measured is 0.035 Î¼m. As such, forming a silicon material layer on the control chip can signify the position which is subjected to micro particle contamination. The slightest contamination position can also be signified, which achieves the closer actual contamination by micro particles as compared to measurement using measuring equipment such as TXRF.

Next referring to FIG. 1, step 160: using measuring equipment to measure the number of particles and defects formed on the control chip of the silicon material layer, then the extent of metal contamination and the micro particles contamination within the fabrication device can be obtained.

Via step 100 to step 160, the silicon material layer formed on the control chip enabling the measuring of metal particles and micro particles, the amount of metal contamination and the micro particles within the fabrication device can be effectively and rapidly detected.

In addition, using existing measuring equipment, for instance, TXRF, to measure the number of particles and defects on the silicon material layer of a treated control chip, does not require additional expensive measuring equipment. Thus, less cost and time is needed to achieve better effect than using measuring equipment, for instance, TXRF.

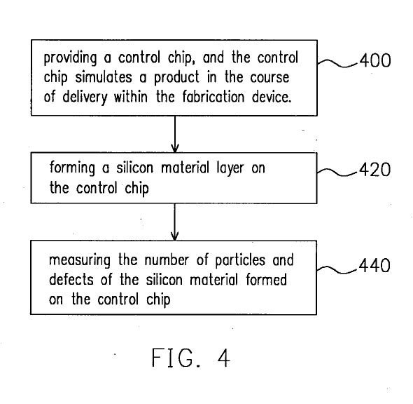

The present invention, other than measuring the metal contamination and detecting the micro particles within the fabrication device, can also simulate a product in actual delivery within the fabrication device, as shown in FIG. 4. FIG. 4 shows a flowchart of detection of metallic contamination and micro particles, using a control chip simulating a product in actual delivery process of the fabrication process.

Step 400: providing a control chip, for instance a vacant wafer or a non-patterned control chip. The control chip simulates a product in the course of delivery within the fabrication device.

Step 420: forming a silicon material layer on the control chip. The silicon material layer is, for instance, polycrystalline silicon, amorphous silicon and epitaxial silicon. The method of forming the silicon material layer, is, for instance, chemical vapour deposition. When the temperature of the silicon material layer formed on the control chip is about, for instance, 600 Â° C. to 750 Â° C., the thickness of the silicon material layer is 550 Ã□. This step signifies the principle of metal impurities and the position of the micro particle being similar to that disclosed in step 104.

Step 440: using measuring device to measure the number of particles and defects of the silicon material layer formed on the control chip via the above steps 400 to 440 can obtain the extent of metal contamination and micro particle with the control chip simulating product in the course of delivery within the fabrication device.

The present invention can also simulate a product undergone metal contamination and micro particles contamination within the fabrication device in the earlier stage of treatment. For example, in the course of etching, before the product is delivered to the main etching chamber, the product is delivered to a vacuuming chamber and is then transferred to a pre-alignment chamber for the earlier stage treatment. The present method can also be used in other fabrication process, for instance, film deposition, dry etching, ion implantation and micro imaging process having different earlier stage treatment by using control chip directly to simulate product in the earlier stage treatment, and then, proceeding to form silicon material layer such that the metal and micro particle contamination on the control chip is significant. In accordance with the present invention, the slightest contamination can also be signified, achieving the state of metal and micro particle closer to the actual product than employing measuring equipment, for instance, TXRF in measuring.

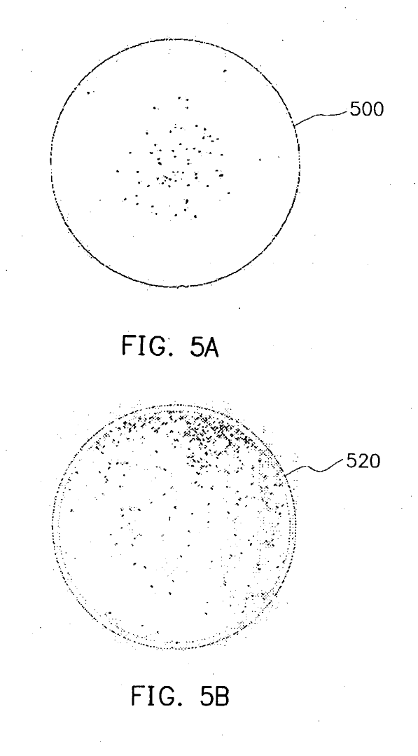

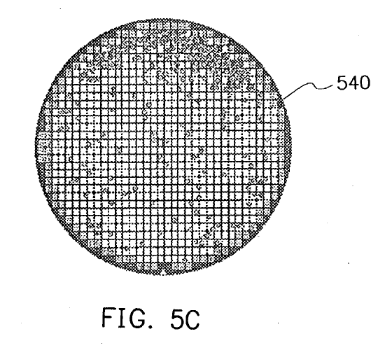

In order to prove the effectiveness of the method of signifying the position of metal impurities and micro particle on the silicon material layer formed on the control chip, an experiment is being accomplished in accordance with the following experimental procedures. After that, the metal and micro particle contamination distribution on the control chip is compared with the impurities distribution on deposited silicon material layer of the product. The experiment procedures are as follows: A control chip is treated using the fabrication device (for example an etching device) based on the above steps, after that the control chip is deposited with silicon material layer, and measuring equipment is used to measure the number of defects on the deposited silicon material layer. The result of the measuring of the deposited silicon material layer of the control chip 500 is shown in FIG. 5A. Next, anther control chip is placed in a fabrication device (for instance, an etching device) to proceed the control chip within the fabrication device without depositing silicon material layer on the control chip, and after that measuring equipment is used to measure the defects formed on the control chip. The result of the measuring on the control chip 520 without depositing a silicon material layer is shown in FIG. 5B. The impurities distributions of the two control chips are compared with that of the product 540 as shown in FIG. 5C. It can be seen that the impurities distribution diagram of the control chip undergone the deposition silicon material layer steps is relatively similar to that of the product.

In view of the above, in accordance with the present invention, it effectively and rapidly reflects the state of the product and discovers the contamination source in the fabrication device or in the course of delivery by forming silicon material layer on the control chip and then measuring the number of defects and particles on the silicon material layer formed on the control chip. Thus, in accordance with the present invention, the cleaning of the device is improved upgrading the capacity of the fabrication process and the yield of the product.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A detection method for metal contamination and micro particles of a fabrication device, the method comprising the steps of:
providing a control chip;
transferring the control chip to a fabrication device so that the control chip is treated by the fabrication device;
removing the control chip from the fabrication device;
forming a silicon material layer on the control chip; and
measuring the number of particles and defects formed on the silicon material layer of the control chip.

2. The detection method of claim 1, wherein the silicon material layer includes polycrystalline silicon.

3. The detection method of claim 1, wherein the silicon material layer includes amorphous silicon.

4. The detection method of claim 1, wherein the silicon material layer includes epitaxial silicon.

5. The detection method of claim 1, wherein the method of forming the silicon material layer includes chemical vapour deposition.

6. The detection method of claim 5, wherein the temperature for forming the silicon material layer is ranging from about 600 Â° C. to 750 Â° C.

7. A detection method for metal contamination and micro particles of a fabrication device, the method comprising the steps of:
providing a control chip to simulate a product of actual transferring within a fabrication device;
forming a silicon material layer on the control chip, the silicon of the silicon material layer and the metal of the surface of the control chip form into bump on the metallic silicon oxide surface; and
measuring the number of particles and defects formed on the silicon material layer of the control chip.

8. The detection method of claim 7, wherein the silicon material layer includes polycrystalline silicon.

9. The detection method of claim 7, wherein the silicon material layer includes amorphous silicon.

10. The detection method of claim 7, wherein the silicon material layer includes epitaxial silicon.

11. The detection method of claim 7, wherein the method of forming the silicon material layer includes chemical vapour deposition.

12. The detection method of claim 11, wherein the temperature for forming the silicon material layer is ranging from about 600 Â° C. to 750 Â° C.

13. A detection method for metal contamination and micro particles of a fabrication device, the method comprising the steps of:
providing a control chip, the surface of the control surface adhered with metallic ions and micro particles;
forming into a silicon material layer on the control chip; and
measuring the number of particles and defects formed on the silicon material layer of the control chip.

14. The detection method of claim 13, wherein the silicon material layer includes polycrystalline silicon.

15. The detection method of claim 13, wherein the silicon material layer includes amorphous silicon.

16. The detection method of claim 13, wherein the silicon material layer includes epitaxial silicon.

17. The detection method of claim 13, wherein the method of forming the silicon material layer includes chemical vapour deposition.

18. The detection method of claim 17, wherein the temperature for forming the silicon material layer is ranging from about 600 Â° C. to 750 Â° C.
